(19) United States
(12) Patent Application Publication
(10) Pub. No.: US 2014/0085828 A1
(43) Pub. Date: Mar. 27, 2014

(54) ELECTRONIC DEVICE WITH HEAT SINK

(71) Applicant: HON HAI PRECISION INDUSTRY CO., LTD., New Taipei (TW)

(72) Inventor: Cheng-Sung Wang, New Taipei (TW)

(73) Assignee: HON HAI PRECISION INDUSTRY CO., LTD., New Taipei (TW)

(21) Appl. No.: 13/669,461

(22) Filed: Nov. 6, 2012

(30) Foreign Application Priority Data
Sep. 27, 2012 (TW) 101135457

(51) Int. Cl. H05K 7/20; F28F 7/00

(52) U.S. Cl. 361/710; 165/185

(57) ABSTRACT

An electronic device includes a circuit board and a heat sink. A chip is mounted on the circuit board. The heat sink includes a base mounted on the chip and a number of heat-dissipation poles extending up from the base. Each pole defines a through hole extending through the base and a top end of the pole.

### BACKGROUND

1. Technical Field

The present disclosure relates to electronic devices and, particularly, to an electronic device with a heat sink.

2. Description of Related Art

Electronic devices, such as computers or servers, ordinarily include a plurality of chips mounted on a circuit board. The chips can generate a great amount of heat and electromagnetic radiation while the electronic devices operate. Thus, heat sinks may be mounted on each chip for heat dissipation. However, a conventional heat sink does not aid in shielding the electromagnetic radiation which may cause electromagnetic interference.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an isometric view of an exemplary embodiment of an electronic device.

FIG. 2 is a cross-sectional view of FIG. 1, taken along the line II-II.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean at least one.

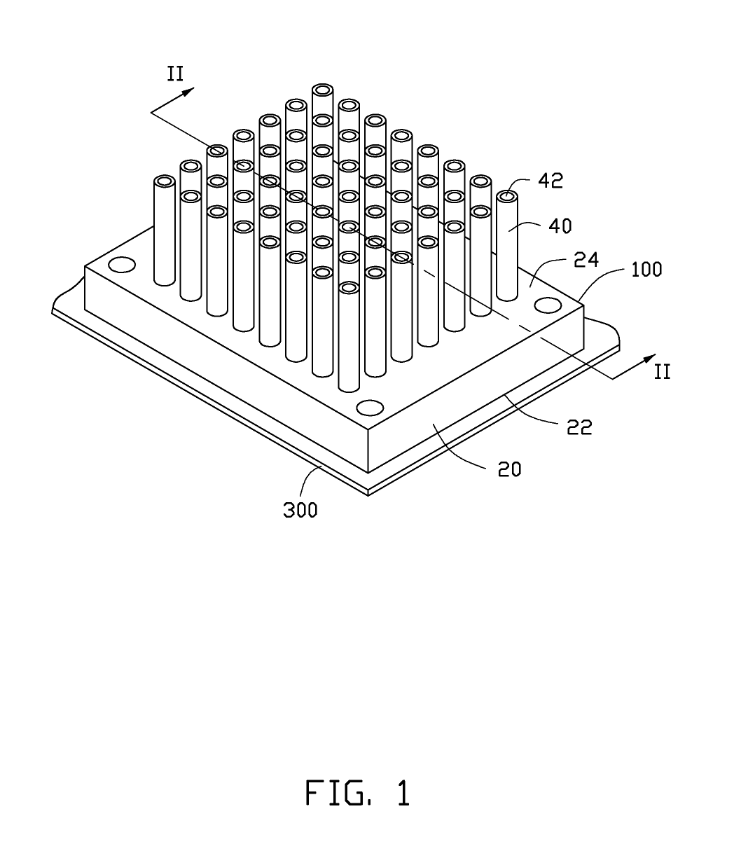

FIG. 1 shows an exemplary embodiment of an electronic device. The electronic device includes a circuit board 300 and a heat sink 100. A chip 302 is mounted on the circuit board 300. The heat sink 100 includes a base 20 mounted on the chip 302 and a plurality of columnar heat-dissipation poles 40 perpendicularly extending up from the base 20. The base 20 includes a bottom surface 22 abutting the chip 302 and a top surface 24 opposite to the bottom surface 22. The poles 40 extend up from the top surface 24. Each pole 40 axially defines a through hole 42 extending through the bottom surface 22 of the base 20 and a top end of the pole 40.

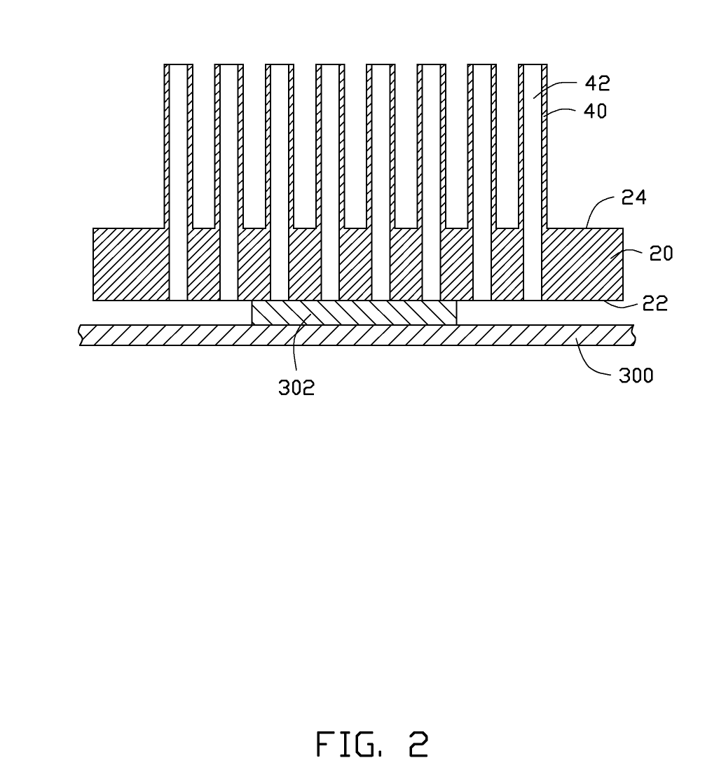

Referring to FIG. 2, in use, the heat sink 100 is installed on the circuit board 300 by screwing or clamping. When the chip 302 operates, a great amount of heat and electromagnetic radiation are generated by the chip 302. The heat is transferred to the poles 40 through the base 20, thus the heat can be removed efficiently because of the large dissipation surface of the poles 40. Some of the electromagnetic radiation enters the through holes 42, and is repeatedly reflected by inner surfaces of the through holes 42 thus weakening the radiation.

Even though numerous characteristics and advantages of the embodiments have been set forth in the foregoing description, together with details of the structure and function of the embodiments, the present disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A heat sink, comprising:
a base; and
a plurality of heat-dissipation poles extending up from the base;
wherein each pole defines a through hole, the through hole further extending through the base.

2. The heat sink of claim 1, wherein the poles are columnar, the through holes of the poles are axially defined in the poles.

3. An electronic device, comprising:
a circuit board comprising a chip mounted on the circuit board; and
a heat sink mounted on the chip, and comprising a base and a plurality of heat-dissipation poles extending up from the base;
wherein each pole defines a through hole, the through hole further extending through the base.

4. The electronic device of claim 1, wherein the poles are columnar, the through holes of the poles are axially defined in the poles.
